(19) United States
(12) Patent Application Publication
(10) Pub. No.: US 2025/0386606 A1
(43) Pub. Date: Dec. 18, 2025

(54) IMAGE SENSOR

(71) Applicant: SAMSUNG ELECTRONICS CO., LTD., Suwon-in (KR)

(72) Inventors: Yeonsoo AHN, Suwon-si (KR); JAMEYUNG KIM, Suwon-si (KR); SUNG IN KIM, Suwon-in (KR)

(73) Assignee: SAMSUNG ELECTRONICS CO., LTD., Suwon-si (KR)

(21) Appl. No.: 19/020,848

(22) Filed: Jan. 14, 2025

(30) Foreign Application Priority Data
Jun. 14, 2024 (KR) 10-2024-0077698
Jun. 20, 2024 (KR) 10-2024-0080553

(51) Int. Cl. H10F 39/00; H10F 39/18

(52) U.S. Cl. CPC H10F 39/80373; H10F 39/014; H10F 39/182; H10F 39/8053; H10F 39/8063; H10F 39/807

(57) ABSTRACT

Disclosed is an image sensor including: a substrate with a pixel region defined by a pixel isolation structure; a first active region and a device isolation structure in the pixel region; and a source follower gate electrode on the pixel region. The first active region has a fin-shaped cross-section, and the source follower gate electrode covers a top surface of the first active region and at least a portion of a lateral surface of the first active region.

### CROSS-REFERENCE TO RELATED APPLICATIONS

This U.S. nonprovisional application claims priority under 35 U.S.C § 119 to Korean Patent Application No. 10-2024-0077698, filed on Jun. 14, 2024, in the Korean Intellectual Property Office, and Korean Patent Application No. 10-2024-0080553, filed on Jun. 20, 2024, in the Korean Intellectual Property Office, the disclosures of which are hereby incorporated by reference in their entireties.

### BACKGROUND

The present disclosure relates to an image sensor, and more particularly, to an image sensor with improved electrical and optical characteristics.

An image sensor is a semiconductor device that transforms optical images into electrical signals. The image sensor may be classified as a charge coupled device (CCD) type or a complementary metal oxide semiconductor (CMOS) type. A CMOS type image sensor may be referred to as a CIS. The CIS may include a plurality of two-dimensionally arranged pixels. Each of the pixels may include a photodiode (PD) which serves to transform an incident light into an electrical signal.

### SUMMARY

One or more example embodiments provide an image sensor in which noise is reduced and transconductance is increased.

According to an aspect of an example embodiment, an image sensor includes: a substrate with a pixel region defined by a pixel isolation structure; a first active region and a device isolation structure in the pixel region; and a source follower gate electrode on the pixel region. The first active region has a fin-shaped cross-section, and the source follower gate electrode covers a top surface of the first active region and at least a portion of a lateral surface of the first active region.

According to another aspect of an example embodiment, an image sensor, includes: a substrate with a pixel region defined by a pixel isolation structure; a first active region and a device isolation structure in the pixel region, the first active region being defined by the device isolation structure; and a source follower gate electrode on the pixel region. The source follower gate electrode includes: a first region; and a second region connected to the first region. The first region is on the first active region. A lower portion of the second region extends into the device isolation structure.

According to another aspect of an example embodiment, an image sensor includes: a substrate with a first pixel group and a second pixel group that are adjacent to each other in a first direction, each of the first pixel group and the second pixel group including four pixels that are sequentially provided along a clockwise direction; a pixel isolation structure in the substrate and extending between the four pixels in each of the first pixel group and the second pixel group; and eight transfer gate electrodes that correspond to the four pixels in each of the first pixel group and the second pixel group. Each of a first pixel of the first pixel group, a third pixel of the second pixel group, and a fourth pixel of the second pixel group includes a source follower gate electrode. The source follower gate electrode includes: a first region on the substrate; and a second region and a third region that are connected to the first region. A bottom surface of each of the second region and the third region extend past a bottom surface of the first region.

### BRIEF DESCRIPTION OF DRAWINGS

The above and other aspects and features will be apparent from the following description of example embodiments, taken in conjunction with the accompanying drawings, in which:

FIG. 1 illustrates a plan view showing an image sensor according to some example embodiments;

FIG. 2 illustrates an enlarged view showing section CUI of FIG. 1 according to example embodiments;

FIGS. 3A, 3B, and 3C illustrate cross-sectional views respectively taken along lines X-X′, Y-Y′, and Z-Z′ of FIG. 2, showing an image sensor according to some example embodiments;

FIG. 4A illustrates an enlarged view showing section CU2 of FIG. 3A according to example embodiments;

FIG. 4B illustrates an enlarged view showing section CU3 of FIG. 3B according to example embodiments;

FIGS. 5A, 5B, 6A, 6B, 6C, 6D, 7A, 7B, 7C, and 7D illustrate cross-sectional views showing a method of fabricating an image sensor according to some example embodiments;

FIG. 8 illustrates a plan view showing an image sensor according to some example embodiments; and

FIG. 9 illustrates a cross-sectional view showing an image sensor according to some example embodiments.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

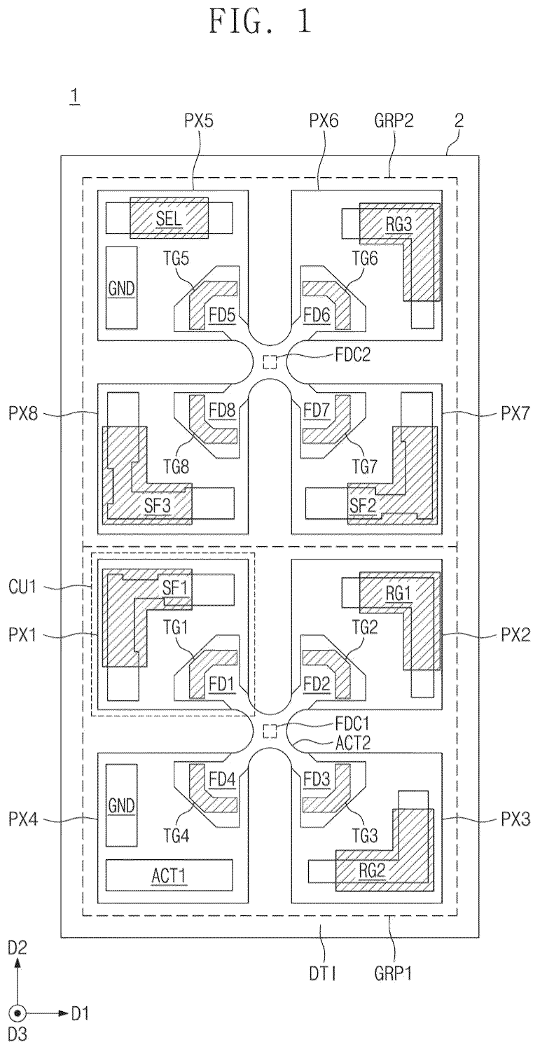

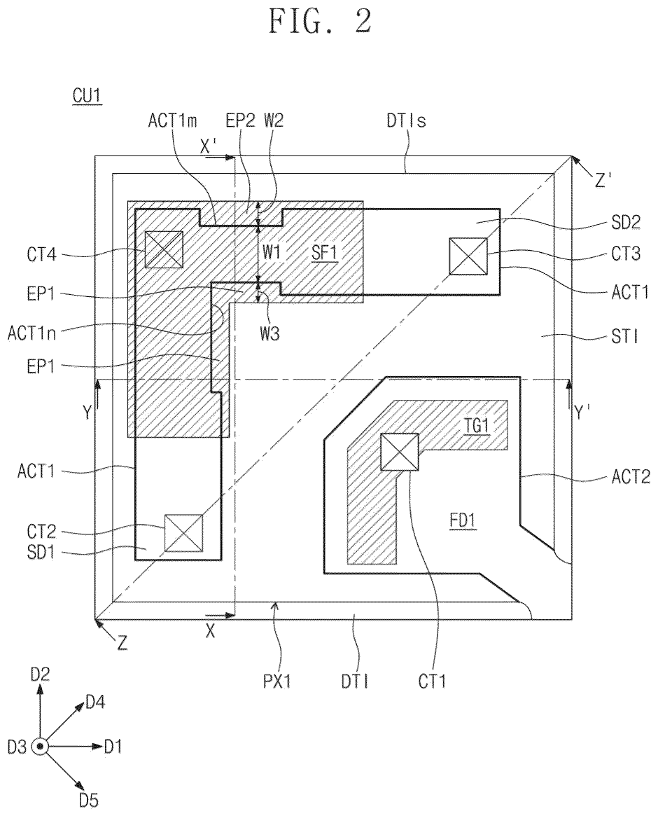

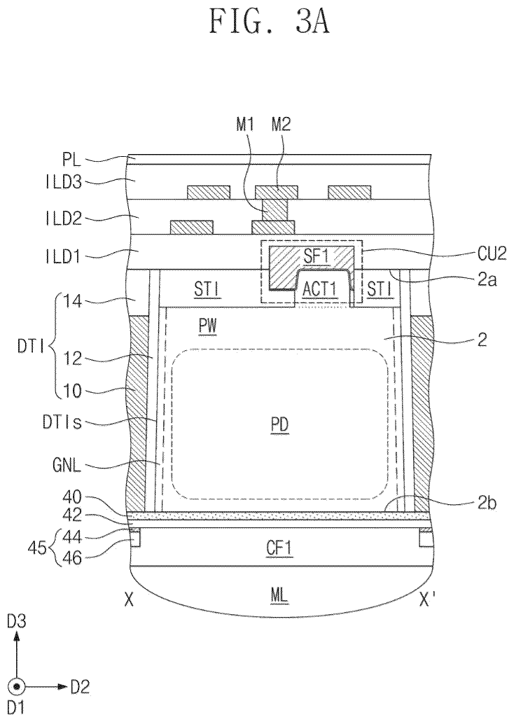

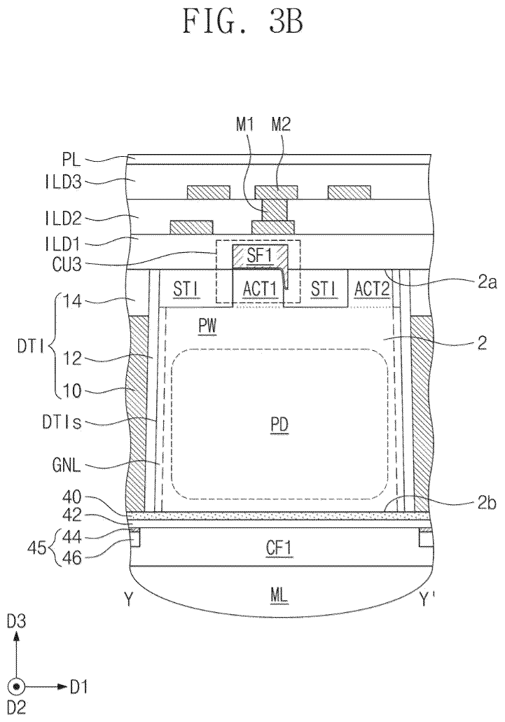

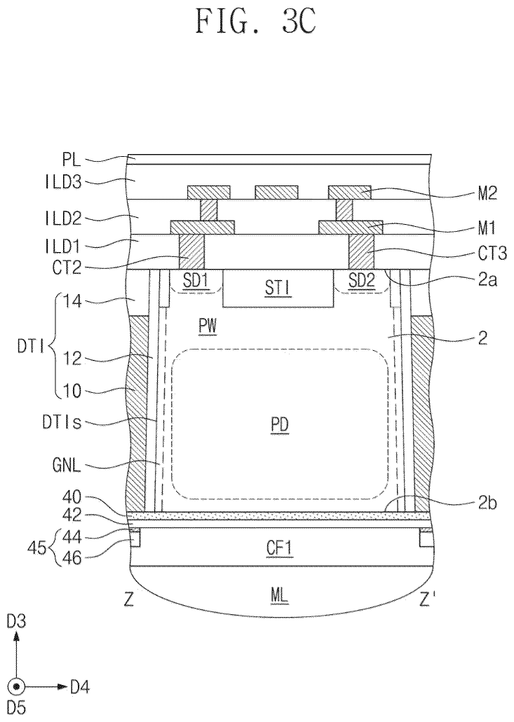

FIG. 1 illustrates a plan view showing an image sensor according to some example embodiments. FIG. 2 illustrates an enlarged view showing section CU1 of FIG. 1. FIGS. 3A, 3B, and 3C illustrate cross-sectional views respectively taken along lines X-X′, Y-Y′, and Z-Z′ of FIG. 2, showing an image sensor according to some example embodiments.

Referring to FIGS. 1, 2, and 3A to 3C, according to some example embodiments, an image sensor 1 may include a substrate 2. The substrate 2 may have a first surface 2a and a second surface 2b that are opposite to each other. The substrate 2 may receive light through the second surface 2b. The substrate 2 may be a monocrystalline wafer or an epitaxial layer including silicon and/or germanium, or a silicon-on-insulator (SOI) substrate. The substrate 2 may include a first active region ACT1 and a second active region ACT2 that are defined by a device isolation part (i.e., a device isolation structure) STI which will be discussed below.

As used herein, a first direction D1 may refer to a direction parallel to the first surface 2a of the substrate 2. A second direction D2 may refer to a direction parallel to the first surface 2a of the substrate 2 and orthogonal to the first direction D1. A third direction D3 may refer to a direction perpendicular to the first surface 2a of the substrate 2. A fourth direction D4 may refer to a direction parallel to the first surface 2a of the substrate 2 and between the first direction D1 and the second direction D2. A fifth direction D5 may refer to a direction parallel to the first surface 2a of the substrate 2 and orthogonal to the fourth direction D4. The substrate 2 may include a plurality of pixels PX1 to PX8 that are two-dimensionally arranged along the first direction D1 and the second direction D2.

For example, according to some example embodiments, the image sensor 1 may include a first pixel group GRP1 and a second pixel group GRP2 on the substrate 2. The first pixel group GRP1 and the second pixel group GRP2 may be adjacent to each other in the second direction D2. The first pixel group GRP1 may include first to fourth pixels PX1 to PX4 that are disposed in a clockwise direction. The second pixel group GRP2 may include fifth to eighth pixels PX5 to PX8 that are disposed in a clockwise direction. The first pixel PX1 may be adjacent, in the second direction D2, to the eighth pixel PX8. The second pixel PX2 may be adjacent, in the second direction D2, to the seventh pixel PX7.

A first source/drain follower gate electrode SF1 may be disposed on the first active region ACT1 of the first pixel PX1. A first reset gate electrode RG1 may be disposed on the first active region ACT1 of the second pixel PX2. A second reset gate electrode RG2 may be disposed on the first active region ACT1 of the third pixel PX3. No gate electrodes may be disposed on the first active region ACT of the fourth pixel PX4. A ground region GND may be disposed on the fourth pixel PX4.

A selection gate electrode SEL may be disposed on the first active region ACT1 of the fifth pixel PX5. A ground region GND may be disposed on the fifth pixel PX5. A third reset gate electrode RG3 may be disposed on the first active region ACT1 of the sixth pixel PX6. A second source/drain follower gate electrode SF2 may be disposed on the first active region ACT1 of the seventh pixel PX7. A third source/drain follower gate electrode SF3 may be disposed on the first active region ACT1 of the eighth pixel PX8.

The first to fourth pixels PX1 to PX4 may respectively include first to fourth transfer gate electrodes TG1 to TG4 and first to fourth floating diffusion sections FD1 to FD4 on the second active regions ACT2. A first common floating diffusion section FDC1 may be disposed on a center of the first pixel group GRP1. The first common floating diffusion section FDC1 may be electrically connected to the first to fourth floating diffusion sections FD1 to FD4.

The fifth to eighth pixels PX5 to PX8 may respectively include fifth to eighth transfer gate electrodes TG5 to TG8 and fifth to eighth floating diffusion sections FD5 to FD8 on the second active regions ACT2. A second common floating diffusion section FDC2 may be disposed on a center of the second pixel group GRP2. The second common floating diffusion section FDC2 may be electrically connected to the fifth to eighth floating diffusion sections FD5 to FD8.

Referring to FIG. 2, the first active region ACT1 may partially extend around the second active region ACT2. When viewed in plan, the first active region ACT1 may have one or more depressions. For example, the first active region ACT1 may include a first depression EP1 and a second depression EP2. A plurality of first depressions EP1 may be provided on an inner sidewall ACT1n of the first active region ACT1. The second depression EP2 may be disposed on an outer sidewall ACT1m of the first active region ACT1. The first depression EP1 may be provided closer than the second depression EP2 to the second active region ACT2. The second depression EP2 may be provided closer than the first depression EP1 to a sidewall DTIs of a pixel isolation part DTI which will be discussed below.

Referring back to FIGS. 2, 3A, and 3B, the substrate 2 may be doped with first impurities to have a first conductivity type. The first impurities may be, for example, boron. The first conductivity type may be, for example, p-type.

A pixel isolation part DTI may be provided in the substrate 2 and the pixel isolation part DTI may separate the first to eighth pixels PX1 to PX8 from each other. The pixel isolation part DTI may include an isolation conductive pattern 10, an isolation dielectric pattern 12, and a buried dielectric pattern 14. The isolation conductive pattern 10 may be spaced apart from the substrate 2. The isolation conductive pattern 10 may include a conductive material having a refractive index different from that of the substrate 2. The isolation conductive pattern 10 may include, for example, impurity-doped polysilicon or metal. The isolation dielectric pattern 12 may be interposed between the isolation conductive pattern 10 and the substrate 2. The buried dielectric pattern 14 may be disposed beneath the isolation conductive pattern 10. The isolation dielectric pattern 12 and the buried dielectric pattern 14 may include a dielectric material having a refractive index different from that of the substrate 2. For example, the isolation dielectric pattern 12 and the buried dielectric pattern 14 may each include silicon oxide. The pixel isolation part DTI may penetrate the substrate 2. The pixel isolation part DTI may have a width that decreases in a direction from the first surface 2a to the second surface 2b.

A negative bias voltage may be applied to the isolation conductive pattern 10. The isolation conductive pattern 10 may serve as a common bias line. Therefore, holes present on a surface of the substrate 2 in contact with the pixel isolation part DTI may be trapped by the isolation conductive pattern 10 to improve dark current properties.

Side ground regions GNL may be disposed adjacent to a sidewall DTIs of the pixel isolation part DTI in the substrate 2. The sidewall DTIs of the pixel isolation part DTI may correspond to an outer sidewall of the isolation dielectric pattern 12. The side ground regions GNL may be doped with first impurities the same as those doped in the substrate 2, and an impurity concentration of the side ground regions GNL may be greater than that of the substrate 2.

A device isolation part STI may be disposed adjacent to the first surface 2a of the substrate 2. The device isolation part STI may be formed to have a single or multiple layer of at least one selected from silicon oxide, silicon nitride, and silicon oxynitride. The device isolation part STI may be provided on the sidewall DTIs of the pixel isolation part DTI.

A photoelectric conversion part PD may be disposed in the substrate 2. A well region PW may be disposed between the photoelectric conversion part PD and the first surface 2a. The well region PW may be doped with, for example, first impurities having a first conductivity type. The first impurities may be, for example, boron. The first conductivity type may be, for example, p-type. A concentration of the first impurities doped in the well region PW may be the same as or greater than a concentration of impurities doped in the substrate 2.

The photoelectric conversion part PD may be doped with second impurities different than the first impurities, thereby having a second conductivity type. The second impurities may be, for example, phosphorus or arsenic. The second conductivity type may be, for example, n-type. An n-type region of the photoelectric conversion part PD and the substrate 2 therearound and/or an n-type region of the photoelectric conversion part PD and a p-type region of the well region PW may form a PN junction to constitute a photodiode, and when light is incident, the PN junction may generate electron-hole pairs.

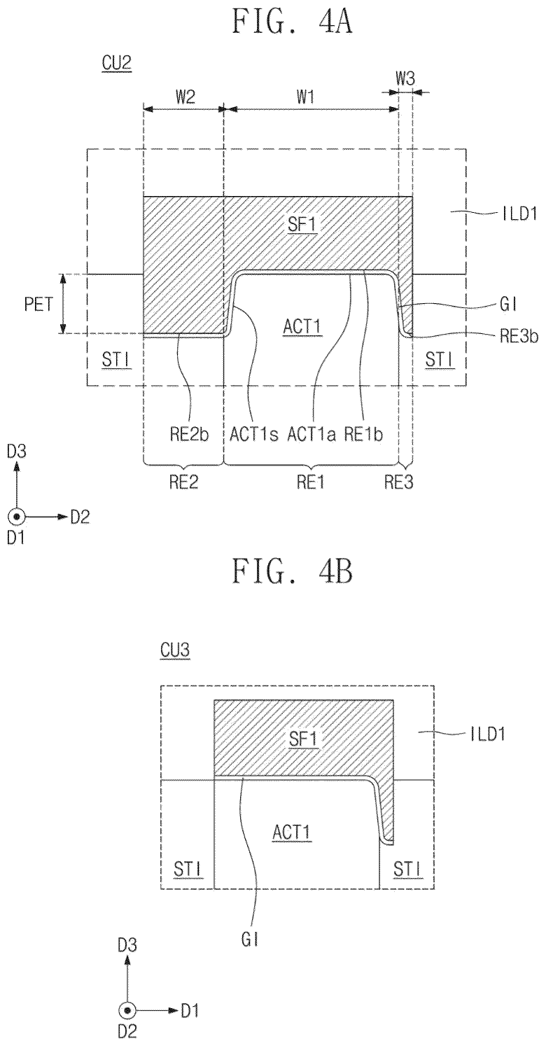

A first source follower gate electrode SF1 may be provided on the device isolation part STI and the first active region ACT1 of the first pixel PX1. The first source follower gate electrode SF1 may include impurity-doped polysilicon. The first source follower gate electrode SF1 will be further discussed in detail with reference to FIGS. 4A and 4B.

Referring to FIG. 2, a first transfer gate electrode TG1 may be disposed on the second active region ACT2. A first contact CT1 may be provided on the first transfer gate electrode TG1. Additionally, a portion of the first transfer gate electrode TG1 may penetrate the substrate 2.

Referring to FIGS. 2 and 3C, a first source/drain pattern SD1 and a second source/drain pattern SD2 may be provided on the first active region ACT1. The first source/drain pattern SD1 and the second source/drain pattern SD2 may be provided adjacent to the first surface 2a of the substrate 2, and may be spaced apart from each other in the fourth direction D4. The first source follower gate electrode SF1 may be provided between the first source/drain pattern SD1 and the second source/drain pattern SD2. One transistor may be constituted by the first source follower gate electrode SF1, the first source/drain pattern SD1, and the second source/drain pattern SD2.

First, second, and third interlayer dielectric layers ILD1, ILD2, and ILD3 and a passivation layer PL may be sequentially stacked on the first surface 2a of the substrate 2. Each of the first, second, and third interlayer dielectric layers ILD1, ILD2, and ILD3 may have a single layer or multiple layers of, for example, at least one selected from silicon oxide, silicon nitride, silicon oxynitride, and porous dielectric. The passivation layer PL may include, for example, silicon nitride.

A second contact CT2 and a third contact CT3 may penetrate the first interlayer dielectric layer ILD1. The second contact CT2 and the third contact CT3 may be in contact with the first source/drain pattern SD1 and the second source/drain pattern SD2. A fourth contact CT4 may penetrate the first interlayer dielectric layer ILDI and may be provided on the first source follower gate electrode SF1.

First metal lines M1 and second metal lines M2 may be respectively provided in the second interlayer dielectric layer ILD2 and the third interlayer dielectric layer ILD3. The first to fourth contacts CT1 to CT4, the first metal lines M1, and the second metal lines M2 may include a conductive material, such as metal.

A fixed charge layer 40 may be disposed on the second surface 2b of the substrate 2. The fixed charge layer 40 may be in contact with the second surface 2b. The fixed charge layer 40 may be formed either of a metal oxide layer including oxygen whose amount is less than its stoichiometric ratio or of a metal fluoride layer including fluorine whose amount is less than its stoichiometric ratio. The fixed charge layer 40 may thus have a negative fixed charge. The fixed charge layer 40 may be formed of one of metal oxide and metal fluoride that include at least one metal selected from hafnium (Hf), zirconium (Zr), aluminum (Al), tantalum (Ta), titanium (Ti), yttrium (Y), and lanthanides. Holes may accumulate around the fixed charge layer 40. Therefore, dark current and white spot may be effectively reduced. For example, the fixed charge layer 40 may include at least one selected from aluminum oxide and hafnium oxide.

An antireflection layer 42 may be disposed on the fixed charge layer 40. The antireflection layer 42 may include, for example, silicon nitride.

A grid 45 may be provided on the antireflection layer 42. The grid 45 may include a first material pattern 44 and a second material pattern 46. The antireflection layer 42 on the photoelectric conversion part PD may be exposed around the first material pattern 44 and the second material pattern 46. The first material pattern 44 may include a material, such as titanium, which is not transparent to light (i.e., is opaque). A sidewall of the second material pattern 46 may be aligned with that of the first material pattern 44. The first material pattern 44 and the second material pattern 46 may prevent crosstalk between adjacent pixels. The second material pattern 46 may include an organic material. The second material pattern 46 may have a refractive index that is, for example, equal to or less than about 1.3.

First color filters CF1 may be disposed on the antireflection layer 42. The first color filter CF1 may include a photoresist material to which a dye or a pigment is added. One first color filter CF1 may be disposed on the first pixel group GRP1. For example, the first to fourth pixels PX1 to PX4 of the first pixel group GRP1 may be covered with the first color filter CF1 having a first color. Additionally, a color filter having a second color filter different from the first color may be provided on the second pixel group GRP2.

Microlenses ML may be disposed on the first color filters CF1. The microlenses ML may have edges that are in contact with and connected to each other.

FIG. 4A illustrates an enlarged view showing section CU2 of FIG. 3A. FIG. 4B illustrates an enlarged view showing section CU3 of FIG. 3B. For example, FIGS. 4A and 4B show cross-sectional shapes of a source follower gate electrode respectively taken along X-X′ line and Y-Y′ line of FIG. 2.

Referring to FIGS. 2, 4A, and 4B, the first active region ACT1 may have a fin-shaped cross-section with a top surface ACT1a and a lateral surface ACT1s. The first source follower gate electrode SF1 may cover the top surface ACT1a and at least a portion of the lateral surface ACT1s of the first active region ACT1. The top surface ACT1a of the first active region ACT1 may be located at a level higher than that of a bottom surface of the first source follower gate electrode SF1.

For example, the first source follower gate electrode SF1 may have a first region RE1, and may also have a second region RE2 and a third region RE3 that are connected to the first region RE1. The third region RE3 may be provided spaced apart from the second region RE2 across the first region RE1. The second region RE2 and the third region RE3 may be integrally connected to the first region RE1, thereby acting as a source follower gate electrode.

The first region RE1 may be provided on the first active region ACT1. The second region RE2 and the third region RE3 may have lower portions that penetrate the device isolation part STI. A length PET along which the second region RE2 and the third region RE3 penetrate the device isolation part STI may range from about 70 nm to about 100 nm. Thus, a bottom surface RE2b of the second region RE2 and a bottom surface RE3b of the third region RE3 may be located at a level lower than that of a bottom surface RE1b of the first region RE1. For example, a height in the third direction D3 of each of the second and third regions RE2 and RE3 may be greater than a height in the third direction D3 of the first region RE1.

The first region RE1 may have a first width W1 in the second direction D2. The second region RE2 may have a second width W2 in the second direction D2. The third region RE3 may have a third width W3 in the second direction D2. For example, the first width W1 may have a size of about 100 nm to about 120 nm. The second width W2 may have a size of about 70 nm to about 100 nm. The third width W3 may have a size of about 20 nm to about 30 nm.

A gate dielectric pattern GI may be provided beneath the first source follower gate electrode SF1. As the first region RE1 is provided on the first active region ACT1, and as the second region RE2 and the third region RE3 are provided on the device isolation part STI, a portion of the gate dielectric pattern GI may be in contact with the substrate 2 and another portion of the gate dielectric pattern GI may be in contact with the device isolation part STI. The gate dielectric pattern GI may be provided between the first active region ACT1 and the first source follower gate electrode SF1, and between the device isolation part STI and the first source follower gate electrode SF1. The gate dielectric pattern GI may include at least one selected from silicon oxide and silicon nitride.

In an image sensor according to some example embodiments, an active region of a source follower gate electrode may have a fin-shaped cross-section, and the source follower gate electrode may cover a top surface and at least a portion of a lateral surface of the active region. Thus, there may be an increase in channel length in the active region and in area of the source follower gate electrode. Therefore, when a source follower transistor is operated, an amount of current may increase to improve transconductance. In addition, there may be an improvement in linearity of voltage-current graph of the image sensor, and a reduction in noise such as random noise and random telegraphy signal.

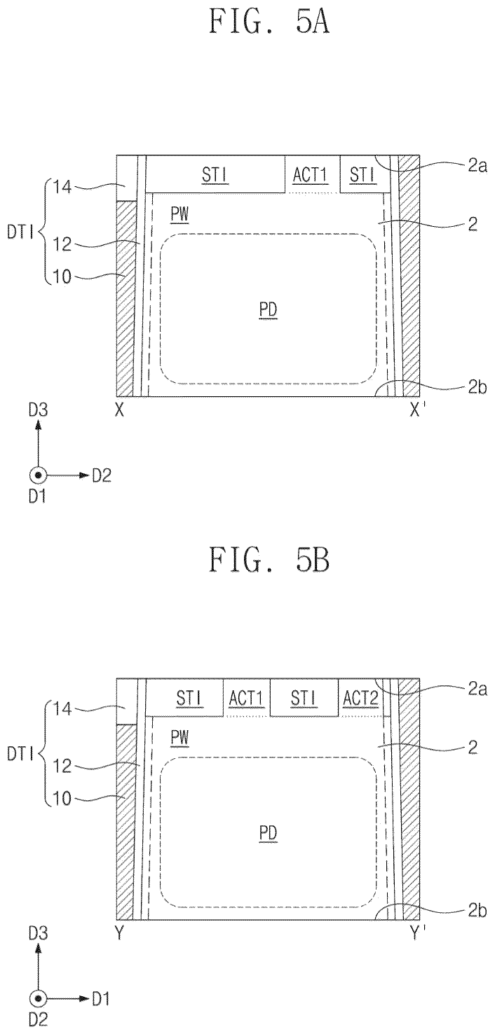

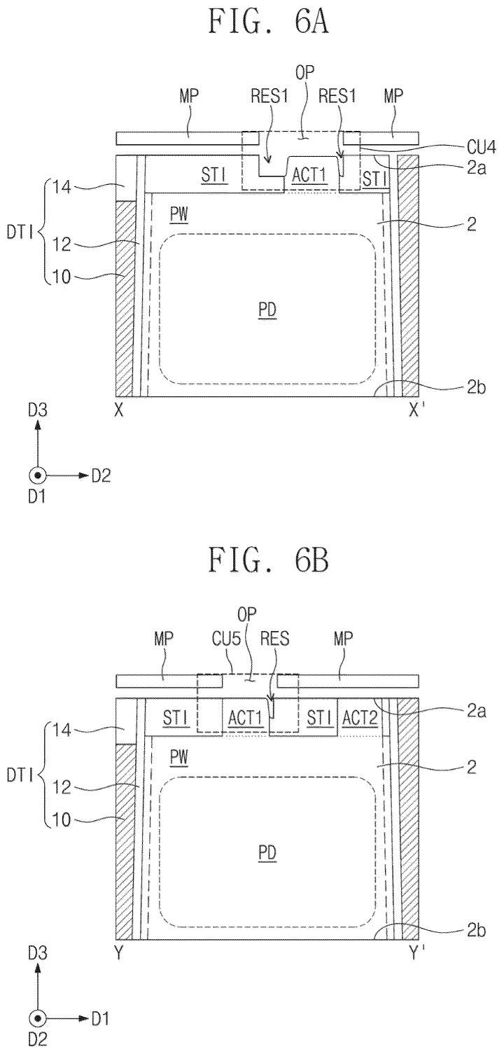

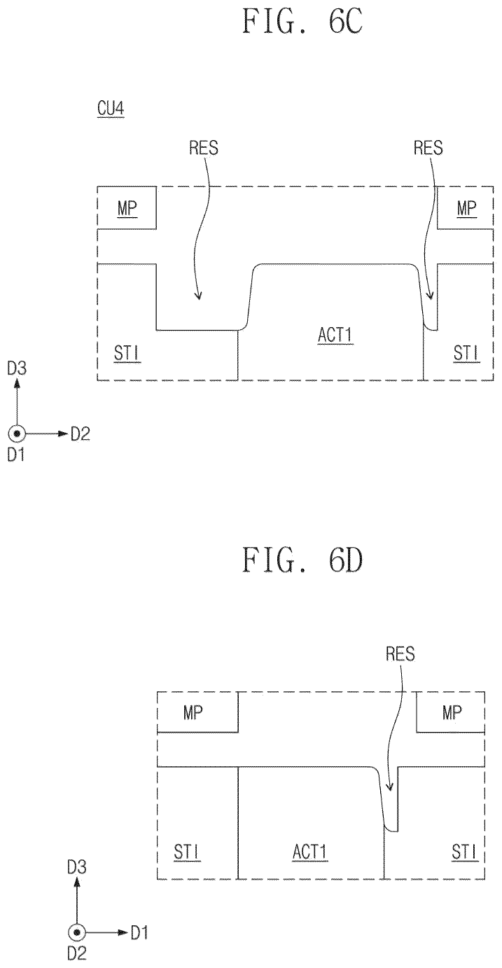

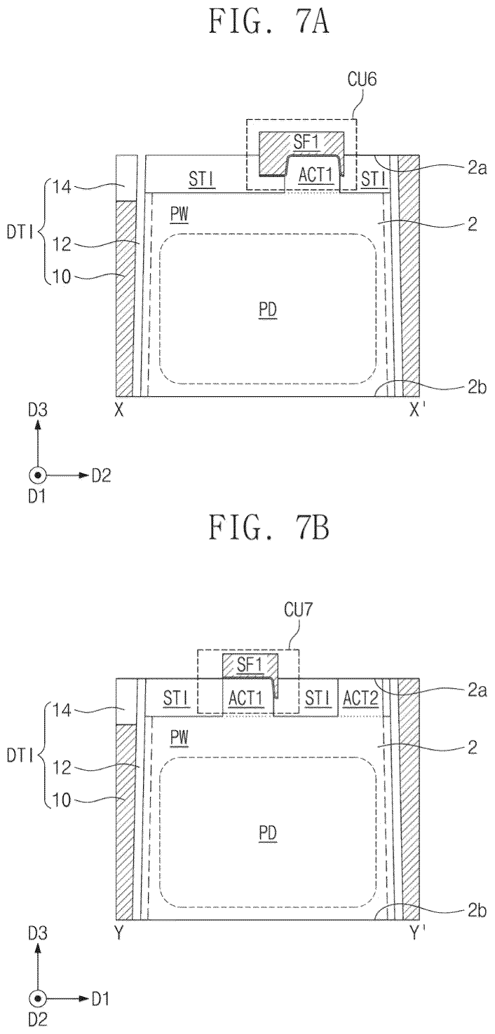

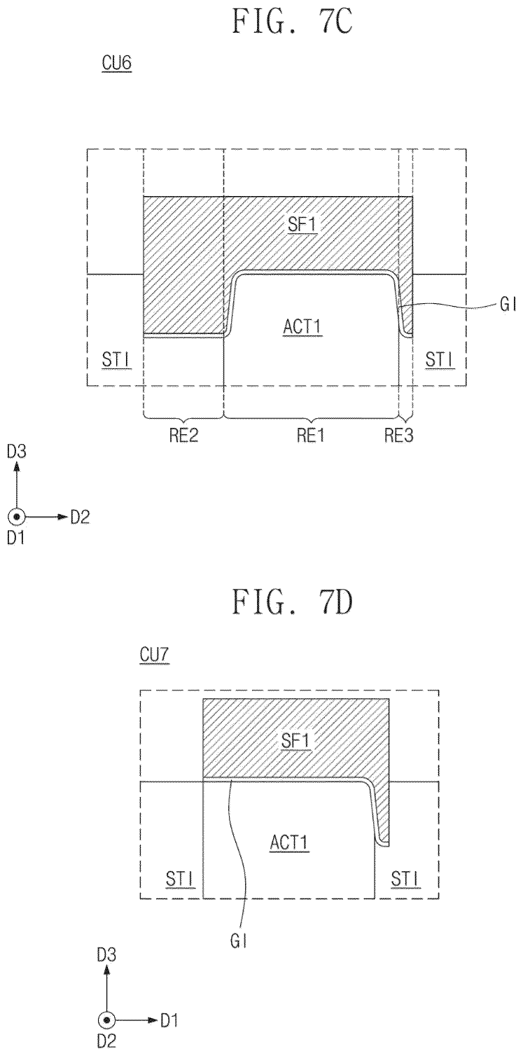

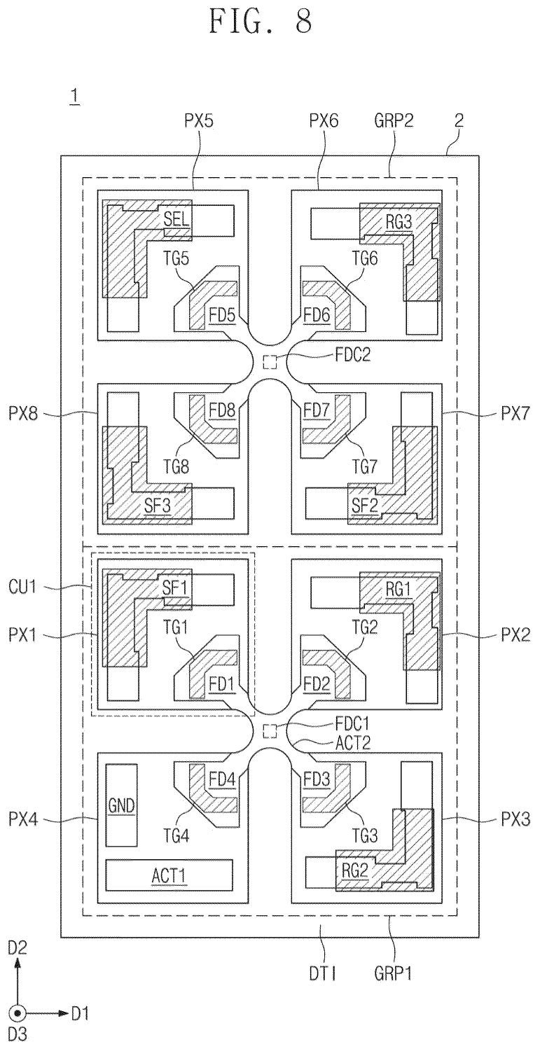

FIGS. 5A, 5B, 6A, 6B, 6C, 6D, 7A, 7B, 7C, and 7D illustrate cross-sectional views showing a method of fabricating an image sensor depicted in FIG. 7D according to some example embodiments. For example, FIGS. 5A, 6A, and 7A illustrate cross-sectional views taken along line X-X′ of FIG. 2. FIGS. 5B, 6B, and 7B illustrate cross-sectional views taken along line Y-Y′ of FIG. 2. FIGS. 6C and 6D illustrate enlarged views respectively showing section CU4 of FIG. 6A and CU5 of FIG. 6B. FIGS. 7C and 7D illustrate enlarged views respectively showing sections CU6 of FIG. 7A and section CU7 of FIG. 7B.

Referring to FIGS. 5A and 5B, a substrate 2 may be provided which has a first surface 2a and a second surface 2b that are opposite to each other. The substrate 2 may have a first conductivity type (e.g., p-type). A device isolation part STI may be formed on the first surface 2a of the substrate 2. The device isolation part STI may be formed by, for example, a shallow trench isolation (STI) process.

A pixel isolation part DTI may be formed to penetrate the device isolation part STI and the substrate 2. The pixel isolation part DTI may include an isolation conductive pattern 10, an isolation dielectric pattern 12, and a buried dielectric pattern 14. The device isolation part STI may define a first active region ACT1 and a second active region ACT2.

A well region PW and a photoelectric conversion part PD may be formed in the substrate 2. The formation of the well region PW may include implanting the substrate 2 with first impurities. The formation of the photoelectric conversion part PD may include implanting the substrate with second impurities different from the first impurities.

Referring to FIGS. 6A, 6B, 6C, and 6D, a mask pattern MP may be disposed on the first surface 2a of the substrate 2. The mask pattern MP may include an opening OP. A recess RES may be formed at a position corresponding to the opening OP. The recess RES may define a region where a first source follower gate electrode SF1 discussed in FIGS. 2, 3A, and 3B will be formed.

The mask pattern MP may be used as an etching mask to etch the substrate 2, for example, a portion of the first active region ACT1 and a portion of the device isolation part

STI. As the mask pattern MP is used to etch a portion of the first active region ACT1 and a portion of the device isolation part STI, the recess RES may be formed. The formation of the recess RES may allow the first active region ACT1 to have a fin-shaped cross-section on an upper portion thereof. Afterwards, the mask pattern MP may be removed.

Referring to FIGS. 7A, 7B, 7C, and 7D, a gate dielectric pattern GI and a first source follower gate electrode SF1 may be sequentially formed on the device isolation part STI and the first active region ACT1.

The formation of the first source follower gate electrode SF1 may include forming, on the first active region ACT1, a metal layer that fills the recess RES on the device isolation part STI, and patterning the metal layer to form a metal pattern. The metal pattern formed on the first active region ACT1 may correspond to a first region RE1 of the first source follower gate electrode SF1 discussed in FIG. 4A. The metal pattern on the device isolation part STI may correspond to a second region RE2 and a third region RE3.

Referring to FIGS. 2, 3A, and 3B, a first floating diffusion section FD1 may be formed on the second active region ACT2. The first floating diffusion section FD1 may be formed by implanting the second impurities different from the first impurities of the substrate 2.

First, second, and third interlayer dielectric layers ILD1, ILD2, and ILD3 and a passivation layer PL may be sequentially formed on the first surface 2a of the substrate 2. First to fourth contacts CT1 to CT4 may be formed to penetrate the first interlayer dielectric layer ILD1, and first metal lines M1 and second metal lines M2 may be provided in the second interlayer dielectric layer ILD2 and the third interlayer dielectric layer ILD3, respectively.

A fixed charge layer 40 and an antireflection layer 42 may be sequentially formed on the second surface 2b of the substrate 2. Afterwards, a first material pattern 44 and a second material pattern 46 may be sequentially formed on the antireflection layer 42.

A first color filter CF1 may be formed on the antireflection layer 42. The first color filter CF1 may be formed to overlap in the third direction D3 with the photoelectric conversion part PD. A microlens ML may be formed on the first color filter CF1, and thus an image sensor may be achieved as shown in FIGS. 2, 3A, and 3B.

FIG. 8 illustrates a plan view showing an image sensor according to some example embodiments. Repeated description similar to that provided above with respect to FIG. 1 may be omitted.

Referring to FIG. 8, when viewed in plan, in the first pixel group GRP1, a shape of the first reset gate electrode RG1 on the second pixel PX2 and a shape of the second reset gate electrode RG2 on the third pixel PX3 may be substantially the same as a rotated shape of the first source follower gate electrode SF1 on the first pixel PX1. For example, when viewed in plan, in the first pixel group GRP1, a shape of the first reset gate electrode RG1 on the second pixel PX2 may be substantially the same as a shape, rotated clockwise by 90 degrees, of the first source follower gate electrode SF1 on the first pixel PX1. For example, when viewed in plan, in the first pixel group GRP1, a shape of the second reset gate electrode RG2 on the third pixel PX3 may be substantially the same as a shape, rotated clockwise by 180 degrees, of the first source follower gate electrode SF1 on the first pixel PX1. The first reset gate electrode RG1 and the second reset gate electrode RG2 may have cross-sections substantially the same as that of the first source follower gate electrode SF1 discussed in FIGS. 3A and 3B.

When viewed in plan, a shape of the third reset gate electrode RG3 on the sixth pixel PX6 included in the second pixel group GRP2 may also be substantially the same as a rotated shape of the first source follower gate electrode SF1 on the first pixel PX1.

For example, when viewed in plan, a shape of the third reset gate electrode RG3 on the sixth pixel PX6 included in the second pixel group GRP2 may be substantially the same as a shape, rotated clockwise by 90 degrees, of the first source follower gate electrode SF1 on the first pixel PX1. A cross-section of the third reset gate electrode RG3 may be substantially the same as that of the first source follower gate electrode SF1.

When viewed in plan, a shape of the selection gate electrode SEL on the fifth pixel PX5 included in the second pixel group GRP2 may also be substantially the same as that of the first source follower gate electrode SF1 on the first pixel PX1. A cross-section of the selection gate electrode SEL may be substantially the same as that of the first source follower gate electrode SF1.

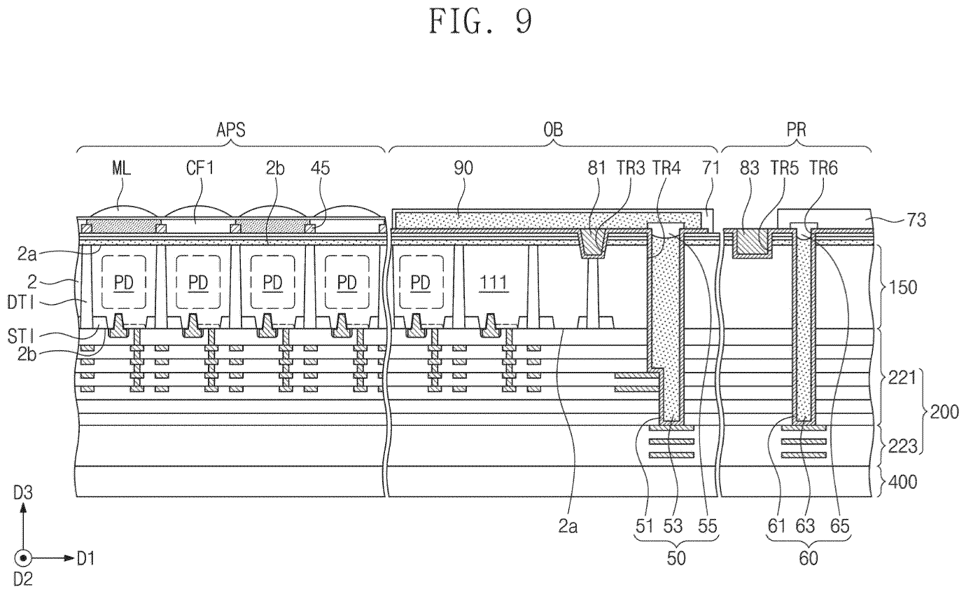

FIG. 9 illustrates a cross-sectional view showing an image sensor according to some example embodiments.

Referring to FIG. 9, an image sensor according to some example embodiments may include a substrate 2 including a pixel array area APS, an optical black area OB, and a pad area PR, and may also include a wiring layer 200 on a first surface 2a of the substrate 2 and a base substrate 400 on the wiring layer 200. The pixel array area APS may include the first to eighth pixels PX1 to PX8 discussed with reference to FIGS. 1 to 8. The wiring layer 200 may include an upper wiring layer 221 and a lower wiring layer 223.

On the optical black area OB, there may be provided a first connection structure 50, a first conductive pad 81, and a bulk color filter 90. The first connection structure 50 may include a first through conductive pattern 51, a dielectric pattern 53, and a first capping pattern 55.

The first through conductive pattern 51 may be provided on a second surface 2b of the substrate 2. The first through conductive pattern 51 may conformally cover an inner wall of a third trench TR3 and an inner wall of a fourth trench TR4. The first through conductive pattern 51 may penetrate a photoelectric conversion layer 150 and the upper wiring layer 221, thereby connecting the photoelectric conversion layer 150 to the wiring layer 200. The first through conductive pattern 51 may be in contact with wiring lines in the lower wiring layer 223.

The first conductive pad 81 may be electrically connected to the isolation conductive pattern 10 of the pixel isolation part DTI depicted in FIG. 3A. The first through conductive pattern 51 may block incidence of light into the optical black area OB. The first through conductive pattern 51 may be formed of a conductive material. The first through conductive pattern 51 may include, for example, titanium or tungsten.

The first conductive pad 81 may be provided in the third trench TR3 to fill an unoccupied portion of the third trench TR3. The first conductive pad 81 may include a metallic material, such as aluminum. A negative bias voltage may be applied through the first conductive pad 81 to the isolation conductive pattern 10. Therefore, the image sensor may be prevented or reduced from white spot and/or dark current.

The dielectric pattern 53 may fill an unoccupied portion of the fourth trench TR4 in which the first through conductive pattern 51 is formed. The dielectric pattern 53 may completely or partially penetrate the photoelectric conversion layer 150 and the wiring layer 200. The first capping pattern 55 may be provided on the dielectric pattern 53.

A bulk color filter 90 may be provided on the first conductive pad 81, the first through conductive pattern 51, and the first capping pattern 55. The bulk color filter 90 may cover the first conductive pad 81, the first through conductive pattern 51, and the first capping pattern 55. A first protection layer 71 may be provided on and encapsulate the bulk color filter 90.

A plurality of pixels PX may also be disposed on the optical black area OB, and a first reference photoelectric conversion part PD′ and a second reference region 111 may be disposed on the pixels PX. The first reference photoelectric conversion part PD′ may provide a first reference charge amount that can occur when light is blocked. The first reference charge amount may be used as a relative reference value when calculating amounts of charges generated from the pixels PX. The second reference region 111 may provide a second reference charge amount that can occur when no photoelectric conversion part PD is present. The second reference charge amount may be used as data for removing process noise.

On the pad area PR, a second connection structure 60, a second conductive pad 83, and a second protection layer 73 may be provided on the substrate 2. The second connection structure 60 may include a second through conductive pattern 61, a dielectric pattern 63, and a second capping pattern 65.

The second through conductive pattern 61 may conformally cover an inner wall of a fifth trench TR5 and an inner wall of a sixth trench TR6. The second through conductive pattern 61 may penetrate the photoelectric conversion layer 150 and the upper wiring layer 221, thereby connecting the photoelectric conversion layer 150 to the wiring layer 200. The second through conductive pattern 61 may be in contact with wiring lines in the lower wiring layer 223. The second through conductive pattern 61 may be electrically connected to wiring lines in the wiring layer 200. The second through conductive pattern 61 may include a metallic material, such as titanium or tungsten.

The second conductive pad 83 may be provided in the fifth trench TR5 to fill an unoccupied portion of the fifth trench TR5. The second conductive pad 83 may include a metallic material, such as aluminum. The second conductive pad 83 may serve as a path for electrical connection with external devices. The dielectric pattern 63 may fill an unoccupied portion of the sixth trench TR6. The dielectric pattern 63 may completely or partially penetrate the photoelectric conversion layer 150 and the wiring layer 200. The second capping pattern 65 may be provided on the dielectric pattern 63. The second protection layer 73 may cover a portion of the second through conductive pattern 61 and the second capping pattern 65.

According to some example embodiments, the first connection structure 50 and/or the pad area PR may be omitted. For example, the second conductive pad 83 may be provided in the lower wiring layer 223, and the photoelectric conversion layer 150 and the wiring layer 200 may be electrically connected through bonding between metal pads.

In an image sensor according to some example embodiments, an active region may have a fin-shaped cross-section, and a source follower gate electrode may cover a top surface and at least a portion of a lateral surface of the active region. Thus, there may be an increase in channel length in the active region and in area of the source follower gate electrode. As a result, as noise is reduced and a current amount is increased when a source follower transistor is operated, the image sensor may improve in electrical and optical characteristics.

While aspects of example embodiments have been particularly shown and described, it will be understood that various changes in form and details may be made therein without departing from the spirit and scope of the following claims.

What is claimed is:

1. An image sensor, comprising:
a substrate comprising a pixel region defined by a pixel isolation structure;
a first active region and a device isolation structure in the pixel region; and
a source follower gate electrode on the pixel region,
wherein the first active region has a fin-shaped cross-section, and
wherein the source follower gate electrode covers a top surface of the first active region and at least a portion of a lateral surface of the first active region.

2. The image sensor of claim 1, further comprising a gate dielectric pattern between the source follower gate electrode and the substrate,
wherein a portion of the gate dielectric pattern is in contact with the substrate, and
wherein another portion of the gate dielectric pattern is in contact with the device isolation structure.

3. The image sensor of claim 1, wherein a top surface of the first active region is at a level higher than a level of a bottom surface of the source follower gate electrode.

4. The image sensor of claim 1, wherein the first active region defines at least one depression.

5. The image sensor of claim 1, wherein the substrate further comprises a second active region defined by the device isolation structure,
wherein the image sensor further comprises a transfer gate electrode on the second active region,
wherein the first active region extends around the second active region, and
wherein the first active region further defines at least one depression.

6. The image sensor of claim 5, wherein the at least one depression comprises a first depression and a second depression,
wherein the first depression is defined along an inner sidewall of the first active region, and
wherein the second depression is defined along an outer sidewall of the first active region.

7. The image sensor of claim 6, wherein the first depression is closer than the second depression to the second active region.

8. The image sensor of claim 6, wherein the second depression is closer than the first depression to a sidewall of the pixel isolation structure.

9. The image sensor of claim 5, wherein the substrate further comprises a floating diffusion section on the second active region.

10. The image sensor of claim 3, wherein the source follower gate electrode comprises impurity-doped polysilicon.

11. An image sensor, comprising:
a substrate comprising a pixel region defined by a pixel isolation structure;
a first active region and a device isolation structure in the pixel region, the first active region being defined by the device isolation structure; and
a source follower gate electrode on the pixel region,
wherein the source follower gate electrode comprises:
a first region; and
a second region connected to the first region,
wherein the first region is on the first active region, and
wherein a lower portion of the second region extends into the device isolation structure.

12. The image sensor of claim 11, wherein the source follower gate electrode further comprises a third region connected to the first region,
wherein the third region is spaced apart from the second region, and
wherein a lower portion of the third region extends into the device isolation structure.

13. The image sensor of claim 12, wherein a length of which the second region and the third region extend into the device isolation structure is in a range of about 70 nm to about 100 nm.

14. The image sensor of claim 12, wherein the first region has a first width in a first direction parallel to a top surface of the substrate, and
wherein the first width is in a range of about 100 nm to about 120 nm.

15. The image sensor of claim 14, wherein the second region has a second width in the first direction,
wherein the third region has a third width in the first direction,
wherein the second width is in a range of about 70 nm to about 100 nm, and
wherein the third width is in a range of about 20 nm to about 30 nm.

16. An image sensor, comprising:
a substrate comprising a first pixel group and a second pixel group that are adjacent to each other in a first direction, each of the first pixel group and the second pixel group comprising four pixels that are sequentially provided along a clockwise direction;
a pixel isolation structure in the substrate and extending between the four pixels in each of the first pixel group and the second pixel group; and
eight transfer gate electrodes that correspond to the four pixels in each of the first pixel group and the second pixel group,
wherein each of a first pixel of the first pixel group, a third pixel of the second pixel group, and a fourth pixel of the second pixel group comprises a source follower gate electrode,
wherein the source follower gate electrode comprises:
a first region on the substrate; and
a second region and a third region that are connected to the first region, and
wherein a bottom surface of each of the second region and the third region extend past a bottom surface of the first region.

17. The image sensor of claim 16, further comprising:
a fixed charge layer on the substrate;
a color filter on the fixed charge layer; and
a microlens on the color filter.

18. The image sensor of claim 16, wherein each of a second pixel of the first pixel group, a third pixel of the first pixel group, and a second pixel of the second pixel group comprises a reset gate electrode, and
wherein a first pixel of the second pixel group comprises a selection gate electrode.

19. The image sensor of claim 18, wherein when viewed in plan, the reset gate electrode in each of the first pixel group and the second pixel group corresponds to a rotated shape of the source follower gate electrode, and
wherein a shape of the selection gate electrode of the second pixel group corresponds to the shape of the source follower gate electrode.

20. The image sensor of claim 16, wherein a height in a vertical direction of each of the second region and the third region is greater than a height in the vertical direction of the first region, and
wherein the vertical direction is perpendicular to a top surface of the substrate.
